(19) United States
(12) Patent Application Publication
(10) Pub. No.: US 2013/0287229 A1
(43) Pub. Date: Oct. 31, 2013

(54) METHOD, SYSTEM AND APPARATUS FOR PROCESSING AUDIO SIGNALS

(71) Applicants: Dong Shi, Singapore (SG); Anders Erik Gustav Norrman, Singapore (SG); Jun Xu, Singapore (SG)

(72) Inventors: Dong Shi, Singapore (SG); Anders Erik Gustav Norrman, Singapore (SG); Jun Xu, Singapore (SG)

(73) Assignee: CREATIVE TECHNOLOGY LTD, Singapore (SG)

(21) Appl. No.: 13/978,399

(22) PCT Filed: Dec. 28, 2011
(86) PCT No.: PCT/SG2011/000451

§ 371 Date: Jul. 4, 2013

(30) Foreign Application Priority Data
Jan. 6, 2011 (SG) 201100106-2

(51) Int. Cl. H03G 3/20

(52) U.S. Cl. CPC H03G 3/20
USPC 381/107

(57) ABSTRACT

A processing method and a processing apparatus for processing an output audio signal from an audio capture device. The output audio signal can be processed by a first processing module in a manner such that a preliminary signal and a first stage processed signal can be derived. The processing method includes providing power estimation signals, providing at least one cross power estimation signal, providing a leakage approximation and providing a control signal estimation.

### FIELD OF INVENTION

The present disclosure generally relates to audio signal processing. More particularly, various embodiments of the disclosure relate to a system, an apparatus and a processing method suitable for processing audio signals in a manner so as to provide an output audio signal having an improved signal quality.

### BACKGROUND

Audio signals are conventionally received and processed by conventional audio processing systems in a manner so as to produce corresponding output audio signals. Audio signals can, for example, be processed by way of amplification. Examples of conventional audio processing systems include microphone based systems.

However, audio processing techniques associated with conventional audio processing systems may be associated with various signal quality issues. For example, output audio signals from conventional audio processing systems may be associated with acoustic echoes which may adversely affect signal quality of the output audio signals.

Thus audio processing techniques associated with conventional audio processing systems may not be capable of processing audio signals in a manner such that output audio signals are of desirable signal quality.

It is therefore desirable to provide a solution to address at least one of the foregoing problems of conventional audio processing techniques.

### SUMMARY OF THE INVENTION

In accordance with a first aspect of the disclosure, a processing method for processing an output audio signal from an audio capture device is provided. The output audio signal can be processed by a first processing module in a manner such that a preliminary signal and a first stage processed signal can be derived.

The processing method includes providing power estimation signals, providing at least one cross power estimation signal, providing a leakage approximation and providing a control signal estimation.

With regard to providing power estimation signals, power estimation signals can be provided based on the preliminary signal and the first stage processed signal in a manner such that a first power estimation signal and a second power estimation signal based on the preliminary signal can be provided based on the preliminary signal and the first stage processed signal respectively.

With regard to providing at least one cross power estimation signal, at least one cross power estimation signal can be provided based on at least one of the first and second power estimation signals.

With regard to providing a leakage approximation, leakage approximation can be provided based on the at least one cross estimation signal.

With regard to providing a control signal estimation, the control signal estimation can be provide based on the preliminary signal, the first stage processed signal and the leakage approximation.

Additionally, the control signal can be communicated to the first processing module for control thereof.

In accordance with a second aspect of the disclosure a processing apparatus suitable for receiving and processing an output audio signal from an audio capture device is provided. The output audio signal can be produced from the audio capture device based on an audio input signal. The input audio signal and the output audio signal can be processed by a first processing module in a manner so as to produce a preliminary signal and a first stage processed signal.

The processing apparatus includes a second processing module coupled to the first processing module in a manner such that the first stage processed signal and the preliminary signals are communicable to the second processing module for processing in a manner so as to produce a control signal and a processed audio signal.

In accordance with a third aspect of the disclosure, a processing apparatus suitable for receiving and processing an output audio signal from an audio capture device is provided. The output audio signal can be produced from the audio capture device based on an audio input signal.

The processing apparatus includes a first processing module and a second processing module. The first processing module can be coupled to the second processing module.

The first processing module includes an input module and a first stage processing module. The first stage processing module can be coupled to the input module.

The first stage processing module can be configured for receiving and processing the audio input signal in a manner so as to produce a preliminary signal.

The input module can be configured to receive the output audio signal and the preliminary signal for processing in a manner so as to produce a first stage processed signal.

The first stage processed signal and the preliminary signals can be communicated to the second processing module for processing in a manner so as to produce a control signal and a processed audio signal.

### BRIEF DESCRIPTION OF THE DRAWINGS

Embodiments of the disclosure are described hereinafter with reference to the following drawings, in which:

FIG. 1a shows a system which includes an audio signal portion and an audio processing portion, according to an embodiment of the disclosure;

FIG. 1b shows the audio signal portion and the audio processing portion of the system of FIG. 1a, in further detail, according to an embodiment of the disclosure;

FIG. 2 shows an exemplary application of the system of FIG. 1a, according to an embodiment of the disclosure;

FIG. 3 shows the audio processing portion of the system of FIG. 1a in further detail, according to an embodiment of the disclosure; and

FIG. 4 shows a flow diagram for a processing method which can be implemented in association with the system of FIG. 1a, according to an embodiment of the disclosure.

### DETAILED DESCRIPTION

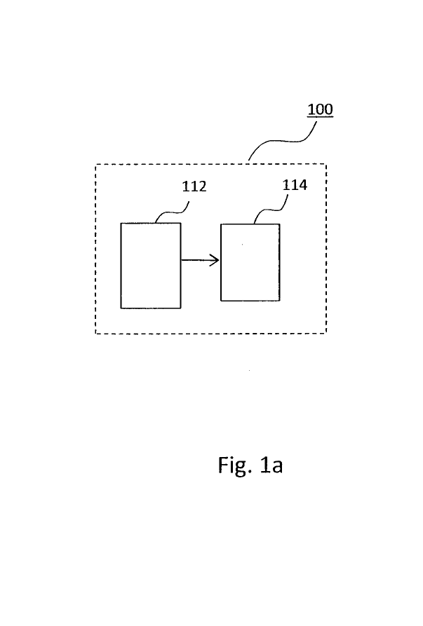

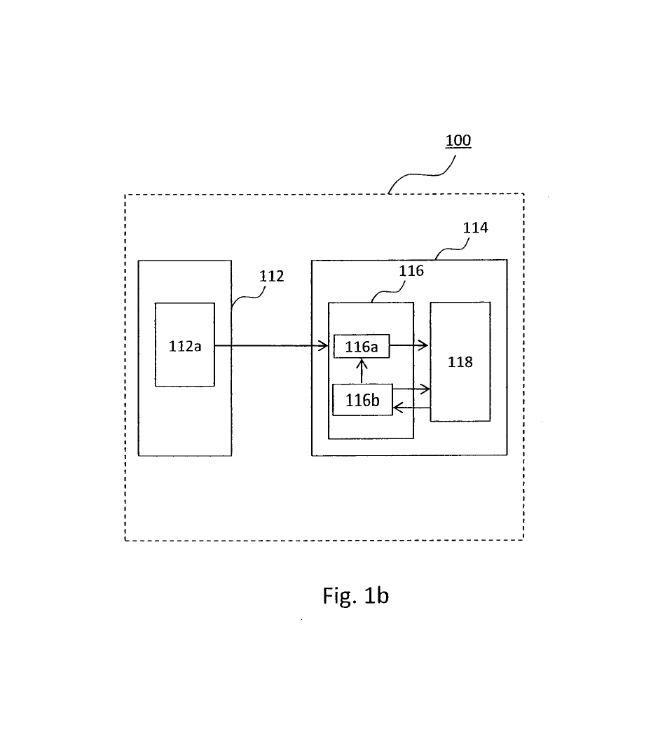

Representative embodiments of the disclosure for addressing one or more of the foregoing problems associated with conventional audio processing techniques are described hereinafter with reference to FIG. 1 to FIG. 4.

Referring to FIG. 1a, a system 100 is shown in accordance with an embodiment of the disclosure. The system 100 includes an audio signal portion 112 and an audio processing portion 114. The audio signal portion 112 can be coupled to the audio processing portion 114.

The audio signal portion 112 can be configured to receive an input audio signal for processing in a manner so as to produce an output audio signal.

The audio processing portion 114 can be configured to receive the input audio signal and the output audio signal for processing in a manner so as to produce a processed audio signal.

The system 100 is shown in further detail in FIG. 1b. Specifically, the audio signal portion 112 and the audio processing portion 114 are shown in further detail.

As shown, the audio signal portion 112 includes an acoustic module 112a. The acoustic module 112a can be configured to process the input audio signal in a manner so as to produce the output audio signal. In this regard, the output audio signal can be based on a processed audio input signal. The acoustic module 112a can be associated with a transfer function. Additionally, the output audio signal can be associated with noise signals. Thus the output audio signal can be further based on a combination of a processed input audio signal and the noise signals.

For example the audio signal portion 112 can be an audio capture device and the acoustic module 112a can be an audio amplifier. The audio capture device can be configured to receive an input audio signal from a user. The audio amplifier can be configured to process the input audio signal in a manner so as to produce an amplified input audio signal. Thus output audio signal can correspond to the amplified input audio signal. Additionally, the audio capture device can also pick up ambient noise signals around the user. Furthermore, the audio amplifier can also be associated with amplifier noise. Thus the aforementioned noise signals can be associated with one or both of the ambient noise signals and amplifier noise.

Further shown, the audio processing portion 114 can include a first processing module 116 and a second processing module 118. The first processing module 116 can be coupled to the second processing module 118. The first processing module 116 can be coupled to the audio signal portion 112.

The first processing module 116 can include an input module 116a and a first stage processing module 116b which is associable with a transfer function. The input module 116a can be coupled to the first stage processing module 116b. Additionally, the input module 116a can be coupled to the audio signal portion 112 in a manner so as to receive the output audio signal. Furthermore, the first stage processing module 116b can be configured to receive and process the input audio signal in a manner so as to produce a preliminary signal. Based on the preliminary and output audio signals, the input module 116a can be configured to produce a first stage processed signal.

The second processing module 118 can be coupled to the first processing module 116 in a manner so as to receive the first stage processed signal and the preliminary signal. Based on the first stage processed signal and the preliminary signal, the second processing module 118 can be configured to produce one or both of a second stage processed signal and a control signal. The second stage processed signal can correspond to the processed audio signal. The control signal can be communicated to the first processing module 116. Particularly, the control signal can be communicated to the first stage processing module 116b for controlling the first stage processing module 116b.

For example, the control signal can be used to vary the transfer function associable with the first stage processing module 116b. Appreciably, as the transfer function associable with the first stage processing module 116b is varied, the preliminary signal can be varied accordingly. Thus the first stage processed signal can also be varied accordingly. In this regard, the control signal can generally be regarded as a feedback mechanism for adaptive control of the first processing module 116.

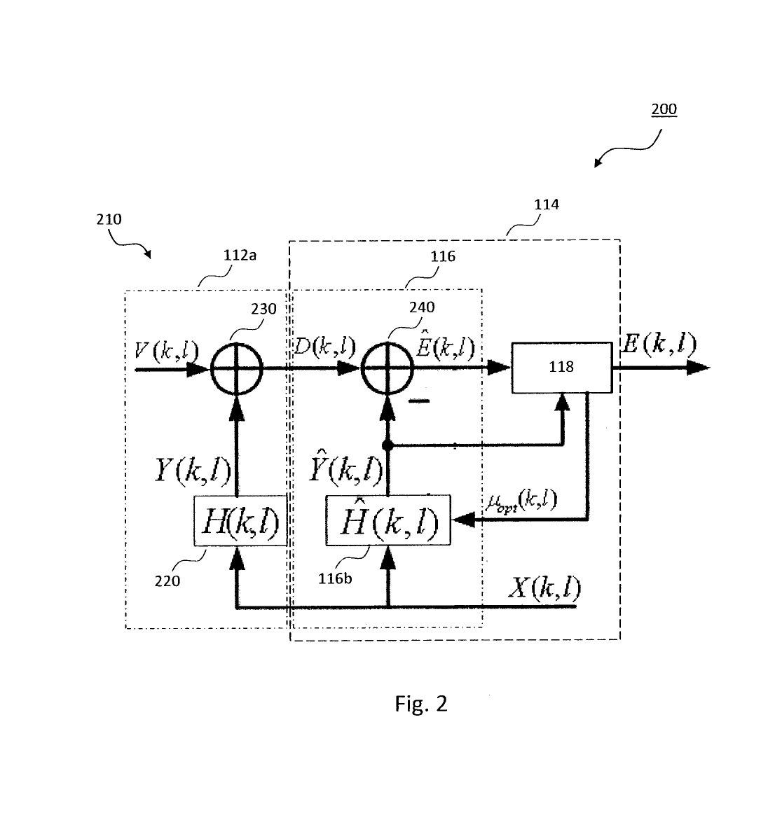

The system 100 will be discussed in further detail hereinafter with reference to an exemplary application 200 as shown in FIG. 2.

In the exemplary application 200, the audio signal portion 112 can be an audio capture device such as a microphone 210 and the acoustic module 112a can be accommodated within the microphone 210. The acoustic module 112a can include a preliminary processing module 220 and a first combiner 230. The preliminary processing module 220 can be coupled to the first combiner 230. The microphone 210 can be configured to capture an input audio signal from a user. Furthermore, the microphone 210 can be configured to produce the aforementioned output audio signal.

In this regard, the aforementioned noise signals, input audio signal and output audio signal can be represented by symbols “V(k,l)” “X(k,l)” and “D(k,l)” respectively. The transfer function of the acoustic module 112a can be based on the preliminary processing module 220 and can correspond to an impulse response represented by symbol “H(k,l)”. Furthermore symbols “k” and “l” can be representative of frequency parameter and time constant parameter associable with any of the aforementioned signals.

The preliminary processing module 220 can be configured to receive and process the input audio signal “X(k,l)” in a manner so as to produce an acoustic signal which can be represented by symbol “Y(k,l)”. The acoustic signal “Y(k,l)” can be associated with the aforementioned processed input audio signal. Thus the acoustic signal “Y(k,l)” can be based on the input audio signal “X(k,l)” and the impulse response “H(k,l)” associable with the preliminary processing module 220.

As mentioned earlier, the output audio signal “D(k,l)” can be based on the combination of the noise signal and the input audio signal “X(k,l)”. Particularly, the output audio signal “D(k,l)” can be based on the combination of the acoustic signal “ Y(k,l)” and the noise signals “V(k,l)”. In this regard, the first combiner 230 combines the noise signals “V(k,l)” and the acoustic signal “Y(k,l)” via, for example, addition to produce the output audio signal “D(k,l)”.

Further, in the exemplary application, the audio processing portion 114 can be a processing apparatus capable of improving signal quality of the output audio signal “D(k,l)” in a manner so as to produce the processed audio signal which can be represented by the symbol “E(k,l)”. In this regard, the processed audio signal “E(k,l)” can correspond to an output audio signal having an improved signal quality. For example, the output audio signal “D(k,l)” can be associated with acoustic echoes which can adversely affect signal quality of the output audio signal “D(k,l)”. Thus the audio processing portion 114 can be an acoustic echo cancellation apparatus configurable to improve signal quality of the output audio signal “D(k,l)” in a manner so as to at least attenuate acoustic echoes associated with the output audio signal “D(k,l)”.

Particularly, the first and second processing modules 116/118 can correspond to a first acoustic echo cancellation stage and a second acoustic echo cancellation stage respectively.

The input module 116a can correspond to a second combiner 240 which is analogous to the first combiner 230. In this regard, the foregoing discussion pertaining to the first combiner 230 analogously applies. Furthermore, the first stage processing module 116b can be analogous to the preliminary processing module 220. In this regard, the foregoing pertaining to the preliminary processing module 220 analogously applies. Thus, the transfer function associable with the first stage processing module 116b can correspond to an impulse response represented by symbol “Ĥ(k,l)”.

The first stage processing module 116b can be configured to receive and process the input audio signal “X(k,l)” in a manner so as to produce the preliminary signal which can be represented by symbol “Ŷ(k,l)”. Thus the preliminary signal “Ŷ(k,l)” can be based on the input audio signal “X(k,l)” and the impulse response “Ĥ(k,l)” associable with the first stage processing module 116b.

The second combiner 240 can be configured to receive and process the output audio signal “D(k,l)” and the preliminary signal “Ŷ(k,l)” in a manner so as to produce the first stage processed signal which can be represented by symbol “Ê(k,l)”. For example, the second combiner 240 can process the output audio signal “D(k,l)” and the preliminary signal “Ŷ(k,l)” in a manner so as to combine both signals via subtraction so as to produce the first stage processed signal “Ê(k,l)”, Thus first stage processed signal “Ê(k,l)” can correspond to a subtraction of the preliminary signal “Ŷ(k,l)” from the output audio signal “D(k,l)”. In this manner, at least a portion of the acoustic echoes associated with the output audio signal “D(k,l)” can be attenuated.

Earlier mentioned, based on the first stage processed signal “Ê(k,l)” and the preliminary signal “Ŷ(k,l)”, the second processing module 118 can be configured to produce one or both of a second stage processed signal and a control signal. The second stage processed signal and the control signal can be represented by symbols “E(k,l)” and “μₒₚₜ(k,l)” respectively.

The control signal “μₒₚₜ(k,l)” can be derived based on equation (1) as follows:

$${μ}_{opt} ( k , l ) = \frac{{σ}_{r}^{2} ( k , l )}{{σ}_{e}^{2} ( k , l )} \qquad ( 1 )$$

where σᵣ²(k,l) can be energy of residual associable with the preliminary signal “Ŷ(k,l)” and σₑ²(k,l) can be energy of associable with first stage processed signal “Ê(k,l)”. Thus σᵣ²(k,l) and σₑ²(k,l) can be estimated based on equations (2) and (3) as shown below:

\hat{σ}ᵣ²(k,l)=η(k,l)σ_{Ŷ}²(k,l)=η(k,l)∥Ŷ(k,l)∥² (2)

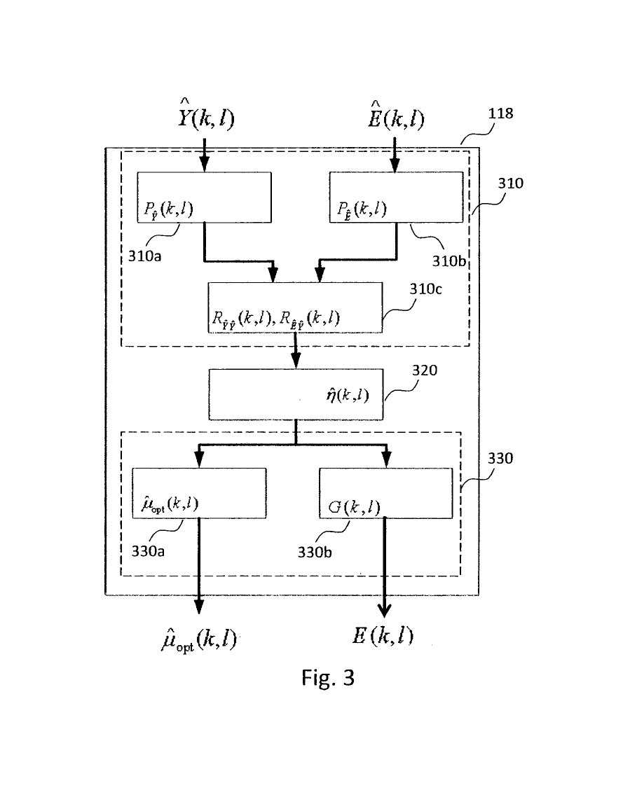

\hat{σ}ₑ²(k,l)=∥Ê(k,l)∥² (3)

where \hat{σ}ᵣ²(k,l) and \hat{σ}ₑ²(k,l) are representative of estimates of σᵣ²(k,l) and σₑ²(k,l) respectively, and η(k,l) can be a leakage factor which will be discussed in further detail with reference to FIG. 3.

Thus based on equations (1), (2) and (3), the control signal can be approximated as shown in equation (4):

$${\hat{μ}}_{opt} ( k , l ) = \hat{η} ( k , l ) \frac{{‖ \hat{Y} ( k , l ) ‖}^{2}}{{‖ \hat{E} ( k , l ) ‖}^{2}} \qquad ( 4 )$$

“\hat{μ}ₒₚₜ(k,l)” can symbolize an approximation associated with the control signal “\hat{μ}ₒₚₜ(k,l)” and “\hat{η}(k,l)” can symbolize an approximation associated with the leakage factor “η(k,l)”.

The audio processing portion 114, specifically the second processing module 118, will be discussed in further detail hereinafter with reference to FIG. 3.

Furthermore, whilst the system 100 is discussed with respect to the foregoing exemplary application 200 which relates to an audio capture device such as a microphone 210, it is appreciable that other applications are also useful. For example, the system 100 can be useful in applications such as video conferencing where a video conferencing apparatus, having an audio capture device, is required for the purpose of the video conference.

Referring to FIG. 3, the second processing module 118 can include a power estimation portion 310 and a leakage approximation portion 320. The second processing module 116 can further include an output portion 330. The power estimation portion 310 can be coupled to the output portion 330. More specifically, the power estimation portion 310 can be coupled to the output portion 330 via the leakage approximation portion 320.

Furthermore, the power estimation portion 310 can be configured to receive and process the preliminary signal “Ŷ(k,l)” and the first stage processed signal “Ê(k,l)” in a manner so as to produce a power estimation signal of each. Yet furthermore, the output portion 330 can be configured to receive and process one or both of the preliminary signal “Ŷ(k,l)” and the first stage processed signal “Ê(k,l)”.

The power estimation portion 310 can include a first power portion 310a, a second power portion 310b and a third power portion 310c. One or both of the first and second power portions 310a/310b can be coupled to the third power portion 310c. Additionally, the first and second power portions 310a/310b can be configured to receive and process the preliminary signal “Ŷ(k,l)” and the first stage processed signal “Ê(k,l)” respectively.

The first power portion 310a can be configured to process the preliminary signal “ Ŷ(k,l)” in a manner so as to produce a power estimation signal thereof. The power estimation signal associated with the preliminary signal “Ŷ(k,l)” can be represented by symbol “P_{Ŷ}(k,l)” and can be derived based on formula (5) as shown below:

P_{Ŷ}(k,l)=(1−α)P_{Ŷ}(k,l−1)+α∥Ŷ(k,l) (5)

where “α” can be an arbitrary smoothing factor. Furthermore, “P_{Ŷ}(k,l)” can be regarded as a first power estimation signal.

The second power portion 310b can be configured to process the first stage processed signal “Ê(k,l)” in a manner so as to produce a power estimation signal thereof. The power estimation signal associated with the first stage processed signal “Ê(k,l)” can be represented by symbol “P_{Ê}(k,l)” and can be derived based on formula (6) as shown below:

P_{Ê}(k,l)=(1−α)P_{Ê}(k,l−1)+α∥Ê(k,l) (6)

where “α” can be an arbitrary smoothing factor as with formula (5) above. Furthermore, “P_{Ê}(k,l)” can be regarded as a second power estimation signal.

The third power portion 310c can be configured to receive one or both of the power estimation signals “P_{Ŷ}(k,l)” and “P_{Ê}(k,l)” from the first and second power portions 310a/310b respectively in a manner so as to produce one or more sets of cross power estimation signals.

For example, based on one or both of the power estimation signals “P_{Ŷ}(k,l)” and “P_{Ê}(k,l)” from the first and second power portions 310a/310b respectively, the third power portion 310c can be configured to produce a first cross power estimation signal and a second cross power estimation signal which can be represented by symbols “R_{ÊŶ}(k,l)” and “R_{ŶŶ}(k,l)” respectively.

More specifically, the first cross power estimation signal “R_{ÊŶ}(k,l)” can be based on both of the power estimation signals “P_{Ŷ}(k,l)” and “P_{Ê}(k,l)”from the first and second power portions 310a/310b respectively, as shown in equation (7) below:

R_{ÊŶ}(k,l)=(1−β(l))R_{ÊŶ}(k,l−1)+β(l)P_{Ŷ}(k,l)P_{Ê}(k,l) (7)

The second cross power estimation signal “R_{ŶŶ}(k,l)” can be based on the power estimation signal “P_{Ŷ}(k,l)” from the first power portion 310a as shown in equation (8) below:

R_{ŶŶ}(k,l)=(1−β(l))R_{ŶŶ}(k,l−1)+β(l)P_{Ŷ}(k,l))² (8)

For equations (7) and (8) above, “β(l)” can be an arbitrary smoothing factor as with “α” in equations (5) and (6) above. “β(l)” can, for example, be derived based on equation (9) as shown below:

$$β ( l ) = {β}_{0} min ( \frac{{σ}_{\hat{Y}}^{2} ( k , l )}{{σ}_{\hat{E}}^{2} ( k , l )} , 1 ) \qquad ( 9 )$$

Furthermore, as mentioned earlier, “l” can be representative of time constant parameter. In this regard, it is appreciable that more than one instance can be associated with any of the aforementioned signals. For example, with regard to equation (7), “l” in “R_{ÊŶ}(k,l)” can refer to a present instance of the first cross power estimation signal at one point in time whereas “l−1” in “R_{ÊŶ}(k,l−1)” can refer to a previous instance of the first cross power estimation signal relative to present instance as represented by “R_{ÊŶ}(k,l)”.

The leakage approximation portion 320 can be configured to receive and process one or more sets of cross power estimation signals from the power estimation portion 310 in a manner so as to produce the earlier discussed “\hat{η}(k,l)” which can symbolize an approximation associated with the leakage factor “η(k,l)”.

For example, based on the first and second cross power estimation signals “R_{ÊŶ}(k,l)”/“R_{ŶŶ}(k,l)”, the leakage approximation portion 320 can be configured to produce “\hat{η}(k,l)” which can be represented by formula (10) as shown below:

$$\hat{η} ( k , l ) = \frac{{R}_{\hat{E} \hat{Y}} ( k , l )}{{R}_{\hat{Y} \hat{Y}} ( k , l )} \qquad ( 10 )$$

The output portion 330 can include a control portion 330a and an attenuation portion 330b. The control portion 330a can be configured to receive and process the preliminary signal “Ŷ(k,l)” and the first stage processed signal “Ê(k,l)”. The attenuation portion 330b can be configured to receive and process the first stage processed signal “Ê(k,l)”.

Specifically, based on the preliminary signal “Ŷ(k,l)”, the first stage processed signal “Ê(k,l)”, and “\hat{η}(k,l)”, the control portion 330a can be configured to obtain an estimation of the control signal “\hat{μ}ₒₚₜ(k,l)” as discussed with reference to formula (4).

Furthermore, the attenuation portion 330b can be associated with a gain factor represented by symbol “G(k,l)”. Thus the attenuation portion 330b can be configured to process first stage processed signal “Ê(k,l)” in a manner so as to attenuate the first stage processed signal “Ê(k,l)” by the gain factor “G(k,l)”.

Specifically, based on an arbitrary predefined constant for controlling attenuation level and “\hat{η}(k,l)” from the leakage approximation portion 320, the attenuation portion 330b can be configured to attenuate the first stage processed signal “Ê(k,l)” by the gain factor “G(k,l)” which can be represented by formula (11) as shown below:

G(k,l)=e^{-Y\hat{η}(k,l)} (11)

where the symbol “Y” denotes the arbitrary predefined constant for controlling attenuation level.

Furthermore, the attenuation portion 330b can be configured to attenuate the first stage processed signal “Ê(k,l)” by the gain factor “G(k,l)” to produce the processed audio signal “E(k,l)” as shown in formula (12) below:

E(k,l)=G(k,l)Ê(k,l) (12)

As discussed earlier, at least a portion of the acoustic echoes associated with the output audio signal “D(k,l)” can be attenuated at the first processing module 116. It is appreciable that at least a further portion of the acoustic echoes associated with the output audio signal “D(k,l)” can be attenuated at the second processing module 118. Thus via a two stage attenuation where the first processing module 116 can constitute a first stage attenuation and the second processing module 118 can constitute a second stage attenuation, acoustic echoes associated with the output audio signal “D(k,l)” can be substantially attenuated to produce the processed audio signal “E(k,l)”.

The first and second stage attenuation can respectively correspond to the aforementioned first and second acoustic echo cancellation stages.

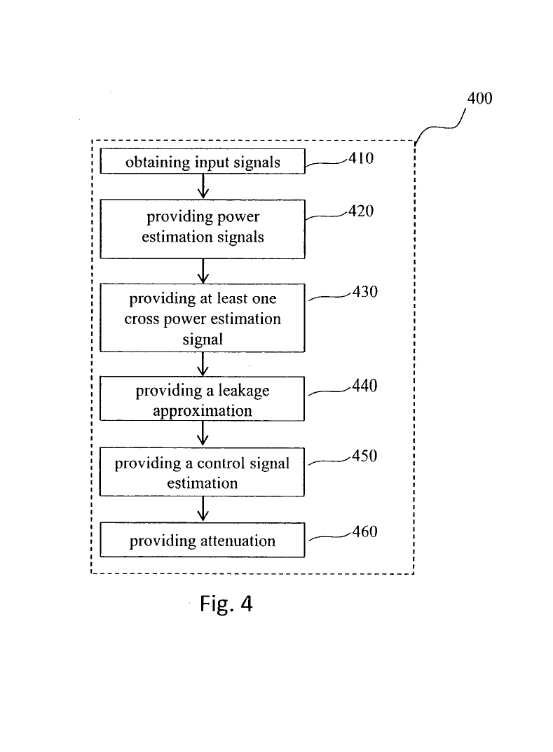

Referring to FIG. 4, a processing method 400, in accordance with another embodiment of the disclosure, can be implemented in association with the system 100.

The processing method 400 can include obtaining input signals 410 where the preliminary signal “Ŷ(k,l)” and the first stage processed signal “Ê(k,l)” can be obtained.

The processing method 400 can also include providing power estimation signals 420 where power estimation signals “P_{Ŷ}(k,l)” and “P_{Ê}(k,l)” associable, respectively, with the preliminary signal “Ŷ(k,l)” and the first stage processed signal “Ê(k,l)” can be obtained.

The processing method 400 can further include providing at least one cross power estimation signal 430 where the first cross power estimation signal “R_{ÊŶ}(k,l)” and the second cross power estimation signal “R_{ŶŶ}(k,l)” can be obtained.

The processing method 400 can yet further include providing a leakage approximation 440 where an approximation associated with the leakage factor “η(k,l)”, symbolized by “\hat{η}(k,l)”, can be obtained based on the first and second cross power estimation signals “R_{ÊŶ}(k,l)”/“R_{ŶŶ}(k,l)”.

Furthermore, the processing method 400 can include providing a control signal estimation 450 where an estimation of the control signal “\hat{μ}ₒₚₜ(k,l)” can be provided based on based on the preliminary signal “Ŷ(k,l)”, the first stage processed signal “Ê(k,l)” and “\hat{η}(k,l)”.

Yet furthermore, the processing method 400 can include providing attenuation 460 where the first stage processed signal “Ê(k,l)” can be attenuated by the gain factor “G(k,l)” to produce the processed audio signal “E(k,l)”

In the foregoing manner, various embodiments of the disclosure are described for addressing at least one of the foregoing disadvantages. Such embodiments are intended to be encompassed by the following claims, and are not to be limited to specific forms or arrangements of parts so described and it will be apparent to one skilled in the art in view of this disclosure that numerous changes and/or modification can be made, which are also intended to be encompassed by the following claims.

1. A processing method for processing an output audio signal from an audio capture device, the output audio signal being processable by a first processing module in a manner such that a preliminary signal and a first stage processed signal are derivable therefrom, the processing method comprising:
providing power estimation signals, power estimation signals being provided based on the preliminary signal and the first stage processed signal in a manner such that a first power estimation signal and a second power estimation signal based on the preliminary signal are providable based on the preliminary signal and the first stage processed signal respectively;
providing at least one cross power estimation signal based on at least one of the first and second power estimation signals;
providing a leakage approximation based on the at least one cross estimation signal; and
providing a control signal estimation in a manner such that a control signal is providable based on the preliminary signal, the first stage processed signal and the leakage approximation,
wherein the control signal is communicable to the first processing module for control thereof.

2. The processing method as in claim 1 further comprising providing attenuation where an attenuation portion associable with a gain factor is provided and the first stage processed signal is processable by the attenuation portion in a manner such that the first stage processed signal is attenuated by the gain factor.

3. The processing method as in claim 2, the gain factor being based on a predefined constant for controlling attenuation level.

4. The processing method as in claim 3, the gain factor being further based on the leakage approximation.

5. The processing method as in claim 1 wherein the first processing module is associable with a transfer function which is variable based on the control signal.

6. The processing method as in claim 1 wherein providing at least one cross power estimation signal comprises providing a first cross power estimation signal and a second cross power estimation signal.

7. The processing method as in claim 6,
wherein the first cross power estimation signal is based on the first and second power estimation signals, and
wherein the second cross power estimation signal is based on the first power estimation signal.

8. A processing apparatus suitable for receiving and processing an output audio signal from an audio capture device, the output audio signal being produced from the audio capture device based on an audio input signal, the input audio signal and the output audio signal being processable by a first processing module in a manner so as to produce a preliminary signal and a first stage processed signal, the processing apparatus comprising:
a second processing module coupled to the first processing module in a manner such that the first stage processed signal and the preliminary signals are communicable to the second processing module for processing in a manner so as to produce a control signal and a processed audio signal.

9. The processing apparatus as in claim 8, the second processing module comprising:
a power estimation portion;
a leakage approximation portion; and
an output portion,
wherein the leakage approximation portion couples the power estimation portion and the output portion.

10. The processing apparatus as in claim 9 wherein the power estimation portion comprises:
a first power portion;
a second power portion; and
a third power portion,
wherein the first and second power portions are coupled to the third power portion.

11. The processing apparatus as in claim 10, wherein the first power portion is configurable to receive and process the preliminary signal in a manner so as to produce a first power estimation signal.

12. The processing apparatus as in claim 11, wherein the second power portion is configurable to receive and process the first stage processed signal in a manner so as to produce a second power estimation signal.

13. The processing apparatus as in claim 12 wherein the third power portion is configurable to receive and process the first power estimation signal and the second power estimation signal in a manner so as to produce at least one cross power estimation signal.

14. The processing apparatus as in claim 13 wherein the at least one cross power estimation signal comprises a first cross power estimation signal and a second cross power estimation signal.

15. The processing apparatus as in claim 14,
wherein the first cross power estimation signal is based on the first and second power estimation signals, and
wherein the second cross power estimation signal is based on the first power estimation signal.

16. The processing apparatus as in claim 15, wherein the leakage approximation portion is configurable to produce an approximated leakage factor based on the first cross power estimation signal and the second cross power estimation signal.

17. The processing apparatus as in claim 16 wherein the output portion comprises a control portion configurable for producing the control signal and an attenuation portion configurable for producing the processed audio signal.

18. The processing apparatus as in claim 17 wherein the control portion is configurable for producing the control signal based on preliminary signal, the first stage processed signal and the approximated leakage factor.

19. The processing apparatus as in claim 18 wherein the attenuation portion is associable with a gain factor and the first stage processed signal is processable by the attenuation portion in a manner such that the first stage processed signal is attenuated by the gain factor.

20. A processing apparatus suitable for receiving and processing an output audio signal from an audio capture device, the output audio signal being produced from the audio capture device based on an audio input signal, the processing apparatus comprising:
a first processing module comprising:
an input module; and
a first stage processing module coupled to the input module, the first stage processing module being configurable for receiving and processing the audio input signal in a manner so as to produce a preliminary signal,
wherein the input module is configurable to receive the output audio signal and the preliminary signal for processing in a manner so as to produce a first stage processed signal, and
a second processing module coupled to the first processing module in a manner such that the first stage processed signal and the preliminary signals are communicable to the second processing module for processing in a manner so as to produce a control signal and a processed audio signal.
